(19) United States
(12) Patent Application Publication
(10) Pub. No.: US 2018/0166289 A1
(43) Pub. Date: Jun. 14, 2018

(54) SUPER HYDROPHOBIC SURFACE FABRICATION METHOD

(71) Applicant: AJOU UNIVERSITY INDUSTRY-ACADEMIC COOPERATION FOUNDATION, Suwon-si, Gyeonggi-do (KR)

(72) Inventors: Chang-Koo KIM, Seoul (KR); Sung-Woon CHO, Suwon-si (KR); Jun-Hyun KIM, Seongnam-si (KR); Jeong-Geun BAK, Suwon-si (KR)

(73) Assignee: Industry-Academic Cooperation Foundation of Ajou University, Suwon-si, Gyeonggi-do (KR)

(21) Appl. No.: 15/580,370

(22) PCT Filed: Jun. 7, 2016
(86) PCT No.: PCT/KR2016/006004

§ 371 Date: Dec. 7, 2017

(30) Foreign Application Priority Data
Jun. 8, 2015 (KR) 10-2015-0080868

(51) Int. Cl. H01L 21/3065; H01L 21/033; H01L 21/02; B32B 33/00

(52) U.S. Cl. CPC H01L 21/3065; H01L 21/0334; B32B 2307/73; B32B 33/00; H01L 21/02112

(57) ABSTRACT

The present invention relates to a method for producing a super-hydrophobic surface, and to a stack having a super-hydrophobic surface prepared by the above method. The super-hydrophobic surface may be realized only by plasma etching and deposition. The super-hydrophobic surface according to the present invention has a very low work of adhesion less than or equal to 3 mJ/m². This super-hydrophobic surface may be applied to various fields including self-cleaning surface, anti-fogging surface, automobile glass surface, and drug delivery device surface.

### BACKGROUND

### Field of the Present Disclosure

The present invention relates to a method of forming a super-hydrophobic surface by plasma etching and deposition.

### Discussion of Related Art

Super-hydrophobicity refers to the physical properties that prevent the substrate surface from getting wet. The methods of implementing the super-hydrophobic surface may be largely classified into a method of changing the surface shape of the substrate and a method of coating a hydrophobic chemical substance on the substrate surface.

The fact that the contact angle of a liquid on a surface with a fine pattern can change is disclosed in the following references: Wenzel [R. N. Wenzel, Ind. Eng. Chem. 28, 988 (1936)] and Cassie [A. B. D. Cassie and S. Baxter, S. Tran, Faraday Soc. 40, 546 (1944)]. Based on this fact, many techniques for controlling the roughness of the surface of the substrate to realize a hydrophobic surface thereof have been reported.

Currently, the following techniques are disclosed for implementing a super-hydrophobic surface: A method of forming a nano-sized ultrafine pattern using a double composite structure (Korean Patent No. 10-0845744); A method of forming a micrometer-sized pattern and re-forming the nano structure on the pattern (Korean Patent Application Publication No. 10-2010-0008579); A method of forming a nanostructure and coating a hydrophobic thin film thereon (Korean Patent Application Publication No. 10-2013-0057238). However, since the above-described methods basically utilize nanostructures, the fabrication method is complicated and the process difficulty is high.

On the other hand, in the case of conventional plasma etching, anisotropy according to the depth of etching may not be realized. Further, the uniformity of the etching pattern could not be guaranteed. Since the etching depth cannot be controlled in an anisotropical manner, it has a limitation in providing the super-hydrophobic surface.

### SUMMARY

The present invention has been made to solve the above-mentioned problems, and, thus, it is an object of the present invention to provide a super-hydrophobic surface which is simple and low in cost.

In one aspect of a first aspect, there is provided a method for forming a super-hydrophobic surface, the method comprising: (a) preparing a substrate having an etch mask disposed thereon, wherein the etching mask has a two-dimensional pattern in which holes having a micrometer scale are arranged at regular intervals; (b) treating said substrate with the etch mask using a plasma of a fluorocarbon containing gas such that a fluorocarbon layer is formed on inner faces of the holes of the etching mask and an top face of the mask; (c) treating said substrate with the etch mask using a plasma capable of etching the fluorocarbon layer and the substrate such that vertical rods are formed in the substrate so as to correspond to the pattern of the mask; (d) repeating the operations (b) and (c) to increase height of the vertical rods; (e) removing the mask from the substrate; and (f) treating the substrate having the vertical rods defined therein using a plasma of a fluorocarbon containing gas to form a fluorocarbon layer on outer faces of the vertically rods.

The micrometer scale means a size of 999 micro meter or less and includes a nanometer scale. The diameter of the mask may be arbitrarily selected based on the diameter of the rod. The method according to the invention can provide a diameter of the rod substantially corresponding to the diameter of the pattern of said mask. Therefore, the rod diameter can be adjusted according to the diameter of the pattern of the mask.

In one embodiment, the operation (e) includes plasma ashing.

In one embodiment, the operation (d) includes repeating the operations (b) and (c) 5 to 500 times.

In one embodiment, the fluorocarbon containing gas is at least one selected from a group consisting of C₄F₈, C₄F₆, C₂F₆, CF₄, and CH₂F₂.

In a second aspect, there is provided a stack having a super-hydrophobic surface, wherein the stack includes: a substrate; and a plurality of vertically oriented rods defined on the substrate, wherein the rods are defined using the method as defined above, wherein the plurality of vertically oriented rods are arranged in a two-dimensional pattern at regular intervals, wherein each of the rods has a diameter equal to or smaller than 4 micrometer. The surface having a plurality of anisotropic rods formed by the method according to the present invention has the following characteristics regardless of the height of the rod when the diameter of the rod is 4 μm or less: the super-hydrophobic surface has a contact-angle equal to or larger than 160° and/or the super-hydrophobic surface has a work of adhesion equal to or smaller than 3 mJ/m².

In a third aspect, there is provided a stack having a super-hydrophobic surface, wherein the stack includes: a substrate; and a plurality of vertically oriented rods defined on the substrate, wherein the rods are defined using the method as defined above, wherein the plurality of vertically oriented rods are arranged in a two-dimensional pattern at regular intervals, wherein each of the rods has a diameter equal to or smaller than 10 micrometer, wherein a height of each of the rods is equal to or larger than 7 micrometer. The surface having a plurality of anisotropic rods formed by the method according to the present invention has the following characteristics when the height of the rod is equal to or larger than 7 micrometer and when the diameter of the rod is 10 μm or less, for example, 7 to 10 μm: the super-hydrophobic surface has a contact-angle equal to or larger than 160° and/or the super-hydrophobic surface has a work of adhesion equal to or smaller than 3 mJ/m².

The present method is much simpler than the conventional method and allows production in a large area. Further, the work of adhesion of the super-hydrophobic surface prepared according to the present invention is 3 mJ/m² or less, which is very small. This super-hydrophobic surface can be applied in various fields including self-cleaning surface, anti-fogging surface, automobile glass surface, and drug delivery device surface.

Further, as for micrometer-scale structures, it is possible to provide better super-hydrophobic surfaces than the nanostructures.

### BRIEF DESCRIPTION OF THE DRAWINGS

FIG. 1 is an SEM photograph of a specimen resulting from a silicon rod being formed repeatedly 48 times.

FIG. 2 shows the height of the silicon substrate according to the number of repetitions of silicon rods formation.

FIGS. 3 and 4 respectively show a contact angle image and a contact angle measurement of water relative to the surface as taken after dropping 0.5 μl of water droplets on the substrate surface having silicon rods formed thereon.

FIGS. 5 and 6 respectively show a contact angle image and a contact angle measurement of water relative to the surface as taken after 0.5 μl of water droplets were contacted on a silicon rod substrate having a fluorocarbon film deposited thereon.

FIG. 7 is a graph showing a change in the work of adhesion of specimen with and without deposition of a fluorocarbon film.

FIG. 8 is a photograph showing the adhesion between 0.5 μl of water drops and a silicon rod substrate (diameter: 1.7 micrometer, height: 2 micrometer).

### DETAILED DESCRIPTIONS

Examples of various embodiments are illustrated and described further below with reference to the drawings. It will be understood that the description herein is not intended to limit the claims to the specific embodiments described. On the contrary, it is intended to cover alternatives, modifications, and equivalents as may be included within the spirit and scope of the present disclosure as defined by the appended claims. For simplicity and clarity of illustration, elements in the figures are not necessarily drawn to scale. The same reference numbers in different figures denote the same or similar elements, and as such perform similar functionality. Also, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

1. Preparation of Si Thin Film Patterned with SiO₂ Mask

A silicon specimen surface patterned with a SiO₂ mask in a cylindrical shape was used. The SiO₂ masks were 1.7, 4, 8, and 10 μm in diameter, respectively, and the spacing between the masks were 2, 4, 8, and 10 μm, respectively. The height of each of the masks was 2 μm.

Although this example uses silicon, the present invention is not limited thereto. Depending on the application, various samples made of insulating film, semiconductor, and conductive polymer may be used. The present invention can be accomplished by performing the etching of a specimen with a plasma capable of etching such a specimen according to the material of the specimen.

In addition, this example uses SiO₂ as an etching mask. The present invention is not limited thereto. Any etching mask may be used as long as a material thereof has a high etching selectivity to a substrate material. Therefore, the etching mask of the present invention is not limited to SiO₂.

The diameter of the etching mask (SiO₂) may be chosen according to the diameter of the rod to be formed on the specimen to be etched. For example, the diameter of the etching mask (SiO₂) can range from tens of nanometers to hundreds of micrometers.

2. Formation of a Structure Comprising a Plurality of Vertically Oriented Rods

The specimen prepared in the above step was etched. Subsequent deposition and etching were repeated to form a structure comprising a plurality of vertically oriented rods.

In the deposition step, the specimen on which the mask is formed is treated with a plasma of a fluorocarbon-containing gas to form a fluorocarbon layer on the inner side face and the top face of the mask pattern. This was carried out under the process conditions of Table 1 below.

TABLE 1

| | | | Flow | | | |
|---|---|---|---|---|---|---|
| | Source | Bias voltage | rate | Pressure | Temperature | Time |
| Gas | power (W) | (−V) | (sccm) | (mTorr) | (° C. ) | (s) |
| C₄F₈ | 800 | 0 | 30 | 30 | 5 | 10 |

The etching step comprises etching the specimen on which the fluorocarbon layer is formed, using a plasma of a gas capable of etching the fluorocarbon layer and the specimen. This etching step forms a rod corresponding to the mask on the substrate. This etching step was performed under the process conditions shown in Table 2 below.

TABLE 2

| | Source | | | | | |
|---|---|---|---|---|---|---|
| | power | Bias | Flow rate | Pressure | Temperature | Time |
| Gas | (W) | voltage (−V) | (sccm) | (mTorr) | (° C. ) | (s) |
| SF₆ | 800 | 50 | 30 | 10 | 5 | 40 |

The number of repetitions of the deposition and etching processes was set at 6, 12, 24, 36 and 48 cycles. As a result, rods having various heights were formed.

The structure including the rods thus formed was cleaned in the following manner.
60 minute ashing in temperature 500° C. furnace,
treatment (SiO₂ mask removal) in 20 vol % HF aqueous solution for 2.5 minutes,

DI water washing: 5 minutes.

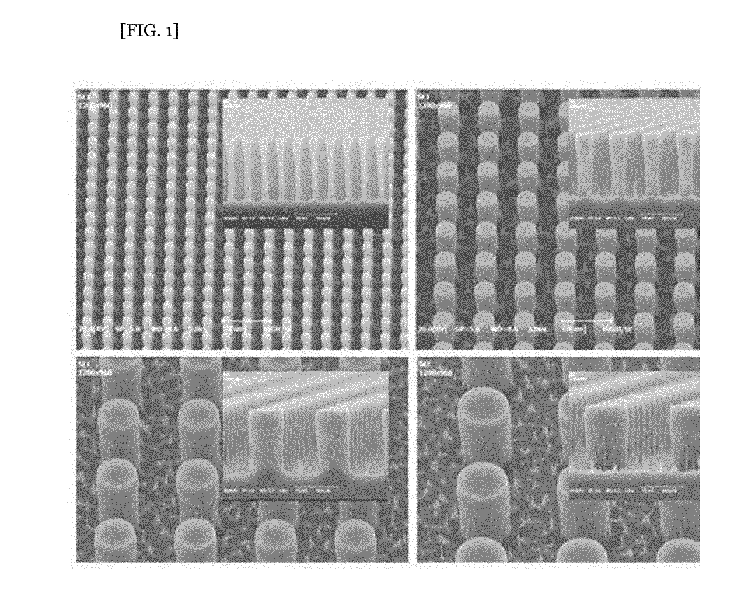

FIG. 1 is an SEM photograph of a specimen resulting from a silicon rod being formed repeatedly 48 times. As shown in FIG. 1, it can be seen that silicon rods having various diameters are formed according to the diameters of the holes defined in the mask pattern.

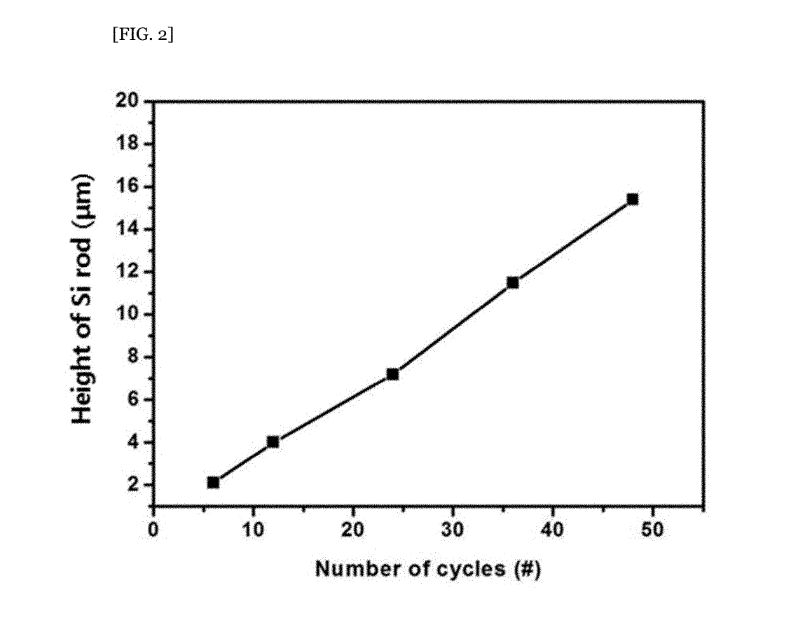

FIG. 2 shows the height of the silicon substrate according to the number of repetitions of silicon rods formation. As the number of cycles increases, the height of the rod increases linearly.

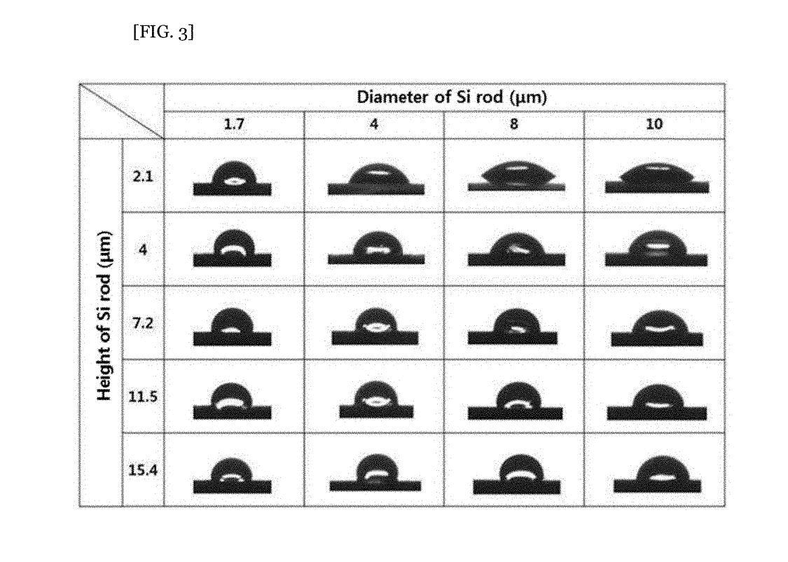

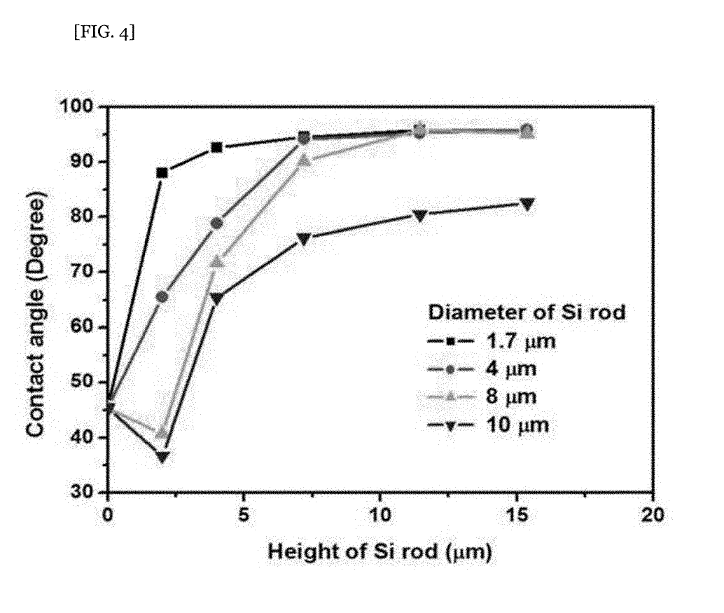

FIGS. 3 and 4 respectively show a contact angle image and a contact angle measurement of water relative to the surface as taken after dropping 0.5 μl of water droplets on the substrate surface having silicon rods formed thereon. When the height of the rod was 0 to 7 micrometer, the contact angle of water decreased as the diameter of the rod increased. When the height of the rod was 7 micrometer or more, the contact angle of the water was defined to be about 94 degree except that the diameter of the rod was 10 micrometer.

3. Plasma Treatment of a Structure Comprising a Plurality of Vertically Oriented Rods

A plurality of vertically oriented rods prepared as described above were treated with plasma of a fluorocarbon-containing gas. Thereby, a fluorocarbon layer was formed on outer faces of the above formed rods. The processing conditions of this treatment are shown in Table 3 below.

TABLE 3

| | Source | Bias | Flow | | Tem- | |
|---|---|---|---|---|---|---|
| | power | voltage | rate | Pressure | perature | Time |
| Gas | (W) | (−V) | (sccm) | (mTorr) | (° C. ) | (s) |
| C₄F₈ | 800 | 0 | 30 | 30 | 5 | 10 |
| | (10 to | | (1 to 500) | (1 to 5000) | | (1 to 100) |
| | 2000) | | | | | |

C₄F₈ gas is one embodiment of the gas used to deposit a fluorocarbon thin film. In addition to C₄F₈, a variety of fluorocarbon based gases such as C₄F₆, C₂F₆, CF₄, CH₂F₂ may be used as the process gas. In addition, the process gas may include a hydrocarbon gas capable of realizing hydrophobic characteristics.

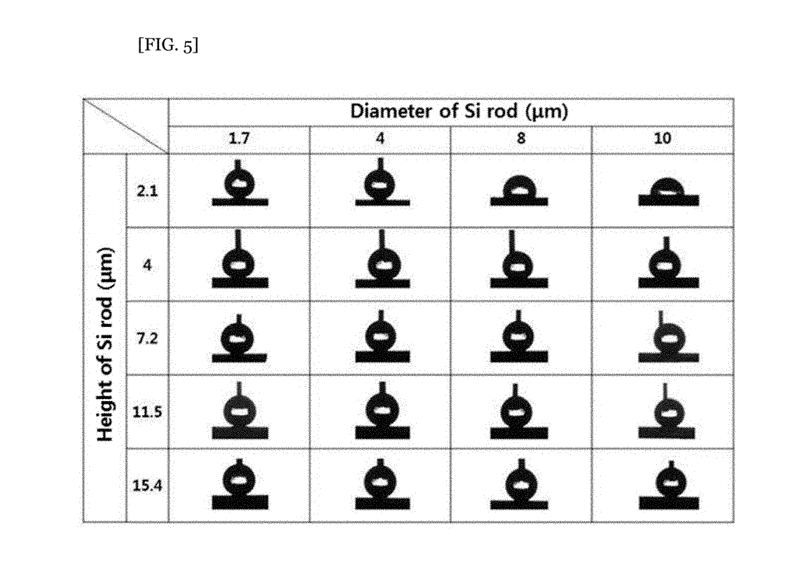

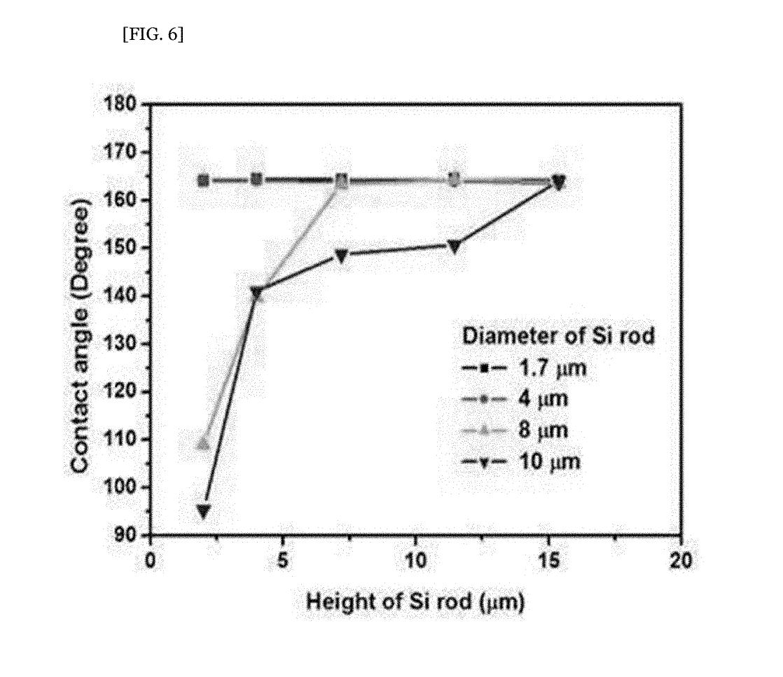

FIGS. 5 and 6 respectively show a contact angle image and a contact angle measurement of water relative to the surface as taken after 0.5 μl of water droplets were contacted on a silicon rod substrate having a fluorocarbon film deposited thereon. When the diameter of the rod was 1.7 and 4 μm, the contact angle of water was about 164° regardless of the height of the rod. This confirms that a super-hydrophobic surface is implemented. A super-hydrophobic surface (contact angle of 160° or more) was realized when the etching depth of the specimen were 7 and 15 μm or more respectively when the rod diameters were 8 and 10 μm.

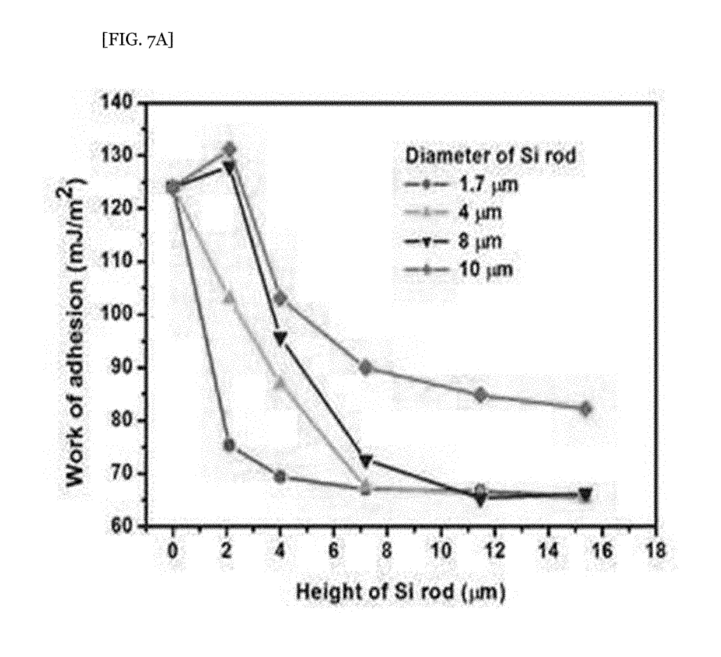

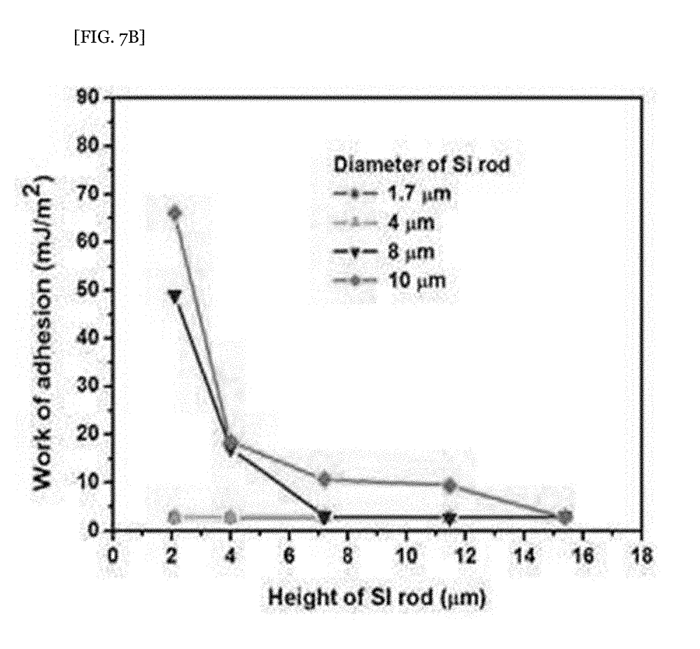

FIG. 7 is a graph showing a change in the work of adhesion of specimen with and without deposition of a fluorocarbon film. The work of adhesion was calculated using the following equation:

Work of adhesion [mJ/m²]=γ_{LV}(1+cos θ)

γ_{LV}: surface tension of water on a solid surface [72.8 mN/m],

θ: contact-angle

The work of adhesion means the amount of work required to remove the water droplets attached to the specimen surface. The smaller the work adhesion, the easier it is to drop water from the surface. As shown in FIG. 7, when the diameter of the rod is 1.7 and 4 μm, the work of adhesion is 3 mJ/m² or less regardless of the height. When the diameter of the rod is 8 and 10 μm, the height of the rod is 7 and 15 μm or more, the work of adhesion is 3 mJ/m₂ or less. These results indicate that droplets may easily be removed by depositing the fluorocarbon thin film on the silicon rod surface.

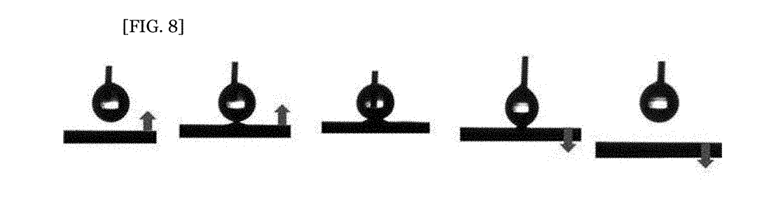

FIG. 8 is a photograph showing the adhesion between 0.5 μl of water drops and a silicon rod substrate (diameter: 1.7 micrometer, height: 2 micrometer). In FIG. 8, the arrow indicates the direction of movement of the substrate. That is, by moving the substrate slowly upwards, droplets adhere to the substrate, and then the substrate moves downward again. Water droplets on a needle with a diameter of 200 μm did not adhere to the substrate. This is because the work of adhesion of the substrate is very small.

While the present invention has been particularly shown and described with reference to exemplary embodiments thereof, it will be apparent to those skilled in the art that various modifications and variations can be made in the present invention without departing from the spirit and scope of the invention as defined in the appended claims.

1. A method for forming a super-hydrophobic surface, the method comprising:
a) preparing a substrate having a mask disposed thereon, wherein the mask has a two-dimensional pattern in which holes having a micrometer scale are arranged at regular intervals;
b) treating said substrate having the mask with a plasma of a fluorocarbon containing gas such that a fluorocarbon layer is formed on inner faces of the holes of the mask;
c) treating said substrate having the mask with a plasma capable of etching the fluorocarbon layer and the substrate such that vertical rods corresponding to the pattern of the mask are formed on the substrate;
d) repeating the steps (b) and (c) to increase height of the vertical rods; and
e) after the step (d), treating the substrate having the vertical rods formed thereon with a plasma of a fluorocarbon containing gas to form a fluorocarbon layer on outer faces of the vertically rods.

2. The method of claim 1, further comprising:
a step of plasma ashing and a step of removing the mask, which are performed between the step (d) and the step (e).

3. The method of claim 1, wherein the step (d) are repeated 5 to 500 times.

4. The method of claim 1, wherein the fluorocarbon containing gas is at least one selected from a group consisting of C₄F₈, C₄F₆, C₂F₆, CF₄, and CH₂F₂.

5. A stack structure having a super-hydrophobic surface, wherein the stack structure comprises:
a substrate; and
a plurality of vertically oriented rods formed on the substrate, wherein the rods are formed by the method of claim 1, wherein the plurality of vertically oriented rods are arranged in a two-dimensional pattern at regular intervals, wherein each of the rods has a diameter equal to or smaller than 4 micrometer.

6. The stack structure of claim 5, wherein the super-hydrophobic surface has a contact-angle equal to or larger than 160°.

7. The stack structure of claim 5, wherein the super-hydrophobic surface has a work of adhesion equal to or smaller than 3 mJ/m².

8. A stack structure having a super-hydrophobic surface, wherein the stack includes:
a substrate; and
a plurality of vertically oriented rods formed on the substrate, wherein the rods are formed by the method of claim 1, wherein the plurality of vertically oriented rods are arranged in a two-dimensional pattern at regular intervals, wherein each of the rods has a diameter equal to or smaller than 10 micrometer, wherein a height of each of the rods is equal to or larger than 7 micrometer.

9. The stack of claim 8, wherein the super-hydrophobic surface has a contact-angle equal to or larger than 160°.

10. The stack of claim 8, wherein the super-hydrophobic surface has a work of adhesion equal to or smaller than 3 mJ/m².
